(19) United States
(12) Patent Application Publication
(10) Pub. No.: US 2026/0045892 A1
(43) Pub. Date: Feb. 12, 2026

(54) IMAGE FORMING APPARATUS

(71) Applicant: CANON KABUSHIKI KAISHA, Tokyo (JP)

(72) Inventors: HIROTAKA MEGURO, Kanagawa (JP); TAKUYA MIYASHITA, Kanagawa (JP)

(21) Appl. No.: 19/289,277

(22) Filed: Aug. 4, 2025

(30) Foreign Application Priority Data
Aug. 6, 2024 (JP) 2024-130098

(51) Int. Cl. H02P 6/15; G01R 31/34; G03G 15/00

(52) U.S. Cl. CPC H02P 6/153; G01R 31/343; G03G 15/5004; G03G 15/80

(57) ABSTRACT

An image forming apparatus, including: a motor which includes a plurality of coils for driving an image forming portion; an inverter which applies a voltage to the plurality of coils; a current detecting portion which detects a current flowing in the plurality of coils; and a control portion which controls the inverter, based on a detection result of the current detecting portion, wherein the control portion controls the inverter so as to stop the application of the voltage during a current detection period for the current detecting portion to detect the current, and wherein the current detecting portion is capable of executing, in the current detection period, a first current detection operation of starting detection of the current after a predetermined settling time elapses and a second current detection operation of starting the detection at an earlier timing than the lapse of the predetermined settling time.

### BACKGROUND

### Field of the Technology The present disclosure relates to an image forming apparatus that forms an image onto a recording material by using an electrophotographic system.

### Description of the Related Art

In an image forming apparatus using the electrophotographic system, a motor such as a stepping motor, a brush motor, or a brushless motor may be used as a drive source for conveying recording materials such as paper. For example, Japanese Patent Application Laid-open No. 2015-104263 proposes a motor control apparatus and an image forming apparatus using a sensorless DC brushless motor that does not have a Hall element for detecting a rotational position of a rotor. In the sensorless DC brushless motor, instead of using a Hall element to detect the position of the rotor, the position of the rotor is detected by a value of a current flowing in a plurality of coils of the motor. Specifically, after an AD converter or the like quantizes analog information of the current value, obtained by a shunt resistor, into digital information, the control apparatus of the motor estimates a rotational position of the rotor. In addition, based on the estimated rotational position, an amount of electrification to each coil is determined by PWM voltage control using an inverter.

As an arrangement of the shunt resistor, there is a system (low-side shunt resistor system) in which the resistor is placed between a low-side switching element and ground in the inverter. The low-side shunt resistor system is cost advantageous in that it allows the use of AD converters with low withstand voltage. In addition, since this system, in which a shunt resistor is provided in each of the plurality of coils of a motor, enables simultaneous detection of the current in each phase of the coils of the motor and accurate detection of the rotor position, rotational speed can be stabilized and unevenness of rotation of the motor can be suppressed. For example, when a 3-phase DC brushless motor is to be provided with shunt resistors, there will be three shunt resistors (3 shunt resistors).

Here, in the image forming apparatus, in a case where the unevenness of rotation of the motor used as the drive source for conveying recording materials is large, image defects may occur. Therefore, the unevenness of rotation of the motor has to be suppressed. For this reason, in a case where a sensorless-control 3-phase DC brushless motor is used as a drive source in an image forming apparatus, a low-side 3-shunt resistor system is often adopted.

In an AD converter that quantizes a current value obtained by a shunt resistor, analog information is charged to a sampling capacitor and then quantized. Generally, an AD converter circuit used in an image forming apparatus resembles a multiplexer with a plurality of inputs. Therefore, switching is required when switching a multiplexer on a controller side to a circuit having analog information that is to be acquired, and this causes a period of instability in the analog information to be read by the AD converter due to switching noise and the like.

When using sensorless DC brushless motor control in an image forming apparatus such as that described in Japanese Patent Application Laid-open No. 2015-104263, there is a concern that a current detection error may become large if a read is performed by the AD converter before this period of instability is over. As a result, unevenness of rotation of the motor may increase. Therefore, after the switching described above is performed, a settling time is provided so that a read by the AD converter is performed only after switching noise subsides.

The low-side 3-shunt resistor system described above requires simultaneous detection of the coil currents of three phases. Therefore, all of the low-side switching elements have to be turned on during the time required for a read by the AD converter in each phase or, in other words, a period of time from the occurrence of switching noise in each phase until convergence thereof. Since high-side switching elements have to be turned off to avoid a through-current, the coils cannot be energized. As a result, on-duty is to be constrained when controlling motor voltage with PWM. For example, if the PWM cycle is 50 μs and the time required for a read by the AD converter is 2 μs, since 2 μs×3 phases=6 μs is required, a maximum duty value is 88%. In other words, a high-duty voltage of nearly 100% cannot be applied, and there may be cases where sufficient voltage cannot be applied when subjected to high loads such as during startup. In order to cope with temporarily high loads such as during startup, motors with specifications that are excessive with respect to a steady load have to be selected, which is cost-prohibitive.

### SUMMARY

The present disclosure is directed to provide a technique that enables an application of a motor drive voltage at a higher duty while stabilizing an image forming operation.

In order to solve the above problems, an image forming apparatus according to the present disclosure includes:
an image forming portion which forms an image onto a recording material;
a motor which generates a drive force for driving the image forming portion and which includes a plurality of coils;
an inverter which applies a voltage to the plurality of coils;
a current detecting portion which detects a current flowing in the plurality of coils; and
a control portion which controls the inverter, based on a detection result of the current detecting portion,
wherein the control portion controls the inverter so as to stop the application of the voltage during a current detection period for the current detecting portion to detect the current, and
wherein the current detecting portion is capable of executing, in the current detection period, a first current detection operation of starting detection of the current after a predetermined settling time elapses and a second current detection operation of starting the detection at an earlier timing than the lapse of the predetermined settling time.

Features of the present disclosure will become apparent from the following description of embodiments with reference to the attached drawings. The following description of embodiments are described by way of example.

### BRIEF DESCRIPTION OF THE DRAWINGS

FIG. 1 is a diagram showing a hardware configuration of an image forming apparatus according to an embodiment of the present disclosure;

FIG. 2 is a diagram showing a control configuration of the image forming apparatus according to the embodiment of the present disclosure;

FIG. 3 is a diagram showing a control configuration of a motor according to the embodiment of the present disclosure;

FIG. 4 is a diagram showing a configuration of the motor according to the embodiment of the present disclosure;

FIG. 5 is a diagram showing a configuration of a current detecting portion according to the embodiment of the present disclosure;

FIG. 6 is a diagram showing a PWM voltage control configuration according to the embodiment of the present disclosure;

FIG. 7A is a diagram showing noise that can occur in analog information during switching when a settling time being a general control is provided for a noise convergence period (first settling time);

FIG. 7B is a diagram showing noise that can occur in analog information during switching when the settling time is provided for a period of an AD read prior to noise convergence (second settling time);

FIG. 8 is a diagram showing a switching operation of settling times according to the embodiment of the present disclosure; and

FIG. 9 is a diagram showing a switching operation of settling times during contact/separation.

### DESCRIPTION OF THE EMBODIMENTS

Modes for implementing the present disclosure will now be described in detail based on embodiments with reference to the drawings. However, it is to be understood that dimensions, materials, shapes, relative arrangements, and the like of components described in the embodiments are intended to be changed as deemed appropriate in accordance with configurations and various conditions of apparatuses to which the disclosure is to be applied. In other words, the scope of the present disclosure is not intended to be limited to the embodiments described below. In addition, while a plurality of features is described in the embodiments, all of the plurality of features is not necessarily essential to the disclosure and the plurality of features may be combined with each other in any way. Moreover, in the accompanying drawings, a same reference numeral will be assigned to a same or similar component and overlapping descriptions will not be repeated.

### First Embodiment

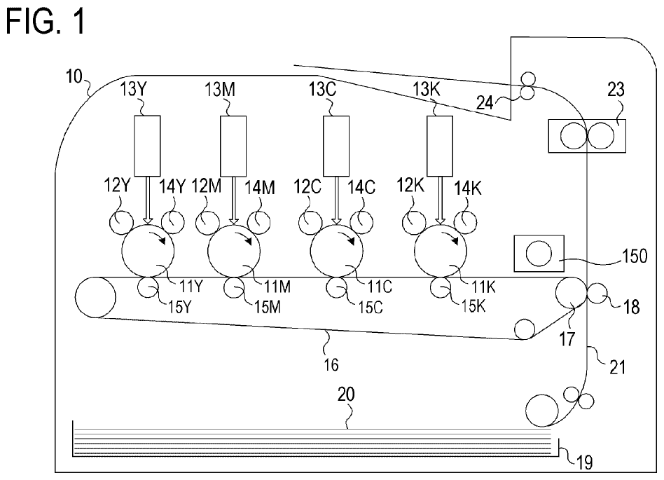

An image forming apparatus according to a first embodiment of the present disclosure will be described with reference to FIGS. 1 to 8.

FIG. 1 is a schematic sectional view showing a hardware configuration example included in the image forming apparatus according to an embodiment of the present disclosure. While a case where the present disclosure is applied to an image forming apparatus that forms an image on a recording material by an electrophotographic system will be described here, the present disclosure is not limited to image forming apparatuses and can be applied to any motor control apparatus that performs sensorless control. An image forming apparatus 10 is a full-color machine that performs printing using toners of four colors: yellow (Y), magenta (M), cyan (C), and black (K). Here, the Y, M, C, and K at the end of reference signs in the drawing indicate which of the four-color toner images above are the components to which the reference signs are attached involved in creating. In the following description, when there is no need to distinguish between the colors, Y, M, C and K at the end of the reference signs shall be omitted as appropriate.

An image forming portion of the image forming apparatus 10 has, with respect to the creation of each of the four color toner images of Y, M, C and K, a photosensitive drum 11 that is an electrophotographic photosensitive member, a charging roller 12 as a charging portion, an exposure portion 13, a developing roller 14 as a developing portion, and the like. After the photosensitive drum 11 is charged by the charging roller 12 to which a charging bias is applied from a high-voltage power supply (not illustrated), an electrostatic latent image is formed by scanning with light by the exposure portion 13. The electrostatic latent image formed on the photosensitive drum 11 as an image bearing member is then developed by a toner borne by the developing roller 14 as a developer bearing member and is manifested as a toner image (developer image). The toner image formed on the photosensitive drum 11 is transferred to an intermediate transfer belt 16 by a primary transfer roller 15. A sheet 20 is conveyed from a cassette 19 through a conveyance path 21 and the toner image is transferred to the sheet 20 from the intermediate transfer belt 16 by a secondary transfer roller 18. Subsequently, the sheet 20 is heated and pressurized by a fixing portion 23 to fix the toner image. The sheet 20 to which the toner image is fixed is discharged to the outside of the image forming apparatus by a paper discharge roller pair 24.

A motor 150 is a motor that generates a drive force to drive the image forming portion including the photosensitive drum 11, the charging roller 12, the exposure portion 13, and the developing roller 14 via a gear mechanism (not illustrated). In addition, the drive force of the motor 150 is used as a drive source for driving a conveyance roller for conveying the sheet 20 via the gear mechanism. In the present embodiment, the motor 150 is constituted of a DC brushless motor.

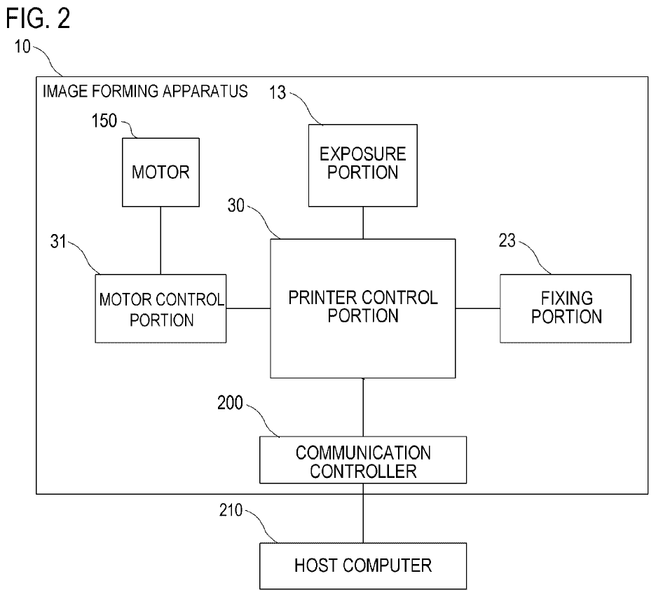

FIG. 2 shows a control configuration of the image forming apparatus. The image forming apparatus 10 includes a printer control portion 30, the exposure portion 13, the fixing portion 23, a motor control portion 31, and a communication controller 200. The printer control portion 30 includes a processor (not illustrated) and a memory that stores a program and various pieces of data for control. The communication controller 200 communicates with a host computer 210 to receive data for image formation from the host computer 210. Based on the received data, the processor of the printer control portion 30 executes an image forming process by executing the program stored in the memory of the printer control portion 30. By sending a signal to the motor control portion 31 and rotationally driving the motor 150, the printer control portion 30 drives rotating members including the photosensitive drum 11 and also performs conveyance control of the sheet 20.

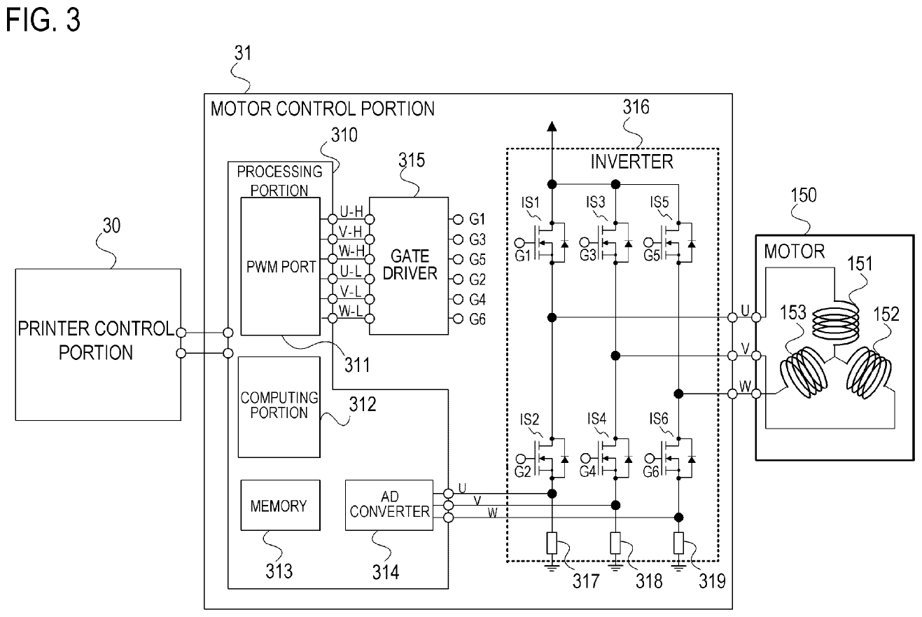

FIG. 3 shows a control configuration of the motor 150. The motor control portion 31 receives a command from the printer control portion 30 and controls the motor 150 under the control of the printer control portion 30. The motor control portion 31 includes a processing portion 310, a gate driver 315, and an inverter 316. The processing portion 310 includes a pulse width modulation (PWM) port 311, a computing portion 312, a memory 313, and an AD (analog/digital) converter 314 and performs serial data communication with the printer control portion 30. The memory 313 stores data and a program for controlling the motor 150. The processing portion 310 performs drive control of the inverter 316 by sending a PWM signal to the gate driver 315 via the PWM port 311.

The inverter 316 is connected to the motor 150 and includes, with respect to the coil of each phase of the motor 150, high-side switching elements IS1, IS3, and IS5 and low-side switching elements IS2, IS4, and IS6. Therefore, when the motor 150 is a 3-phase (U phase, V phase, and W phase) motor such as that shown in FIG. 3, the inverter 316 is a 3-phase inverter constituted of the six switching elements IS1 to IS6. The switching elements IS1 to IS6 of the inverter 316 are constituted of transistors or FETs. Terminals (G1 to G6) for controlling on/off states of the switching elements IS1 to IS6 of the inverter 316 are connected to the gate driver 315 and on/off states of the switching elements IS1 to IS6 are controlled according to a PWM signal from the PWM port 311. For example, by changing an applied voltage of the G1 terminal of the gate driver 315 based on the PWM signal output from a U-H terminal of the PWM port 311, the gate driver 315 controls the G1 terminal of the inverter 316 to switch the switching element IS1 on/off.

By controlling on/off states of the internal switching elements IS1 to IS6, the inverter 316 can control a coil current that flows in each of the coils 151 (U phase), 152 (V phase), and 153 (W phase) of the motor 150. Shunt resistors 317, 318, and 319 are arranged between the low-side switching elements IS2, IS4, and IS6 in the inverter 316 and ground. The current flowing in each of the coils 151 to 153 is converted into a voltage by the shunt resistors 317, 318, and 319 connected in series to a ground terminal of the inverter 316 so as to correspond to each of the coils 151 to 153 and converted into a digital value by the AD converter 314. The computing portion 312 measures a coil current of each phase based on the digital value converted by the AD converter 314. The memory 313 functions to store acquired coil current data.

Here, in order to convert the coil current to voltage at each of the shunt resistors 317, 318, and 319, the low-side switching elements IS2, IS4, and IS6 must be turned on to bring each of the shunt resistors 317, 318, and 319 and the coil of each phase into a conducted state. Therefore, the high-side switching elements IS1, IS3, and IS5 must be turned off for the purpose of avoiding through-current. For example, when the currents in each of the coils 151 (U phase), 152 (V phase), and 153 (W phase) are detected simultaneously, the high-side switching elements IS1, IS3, and IS5 are all off and the low-side switching elements IS2, IS4, and IS6 are all on.

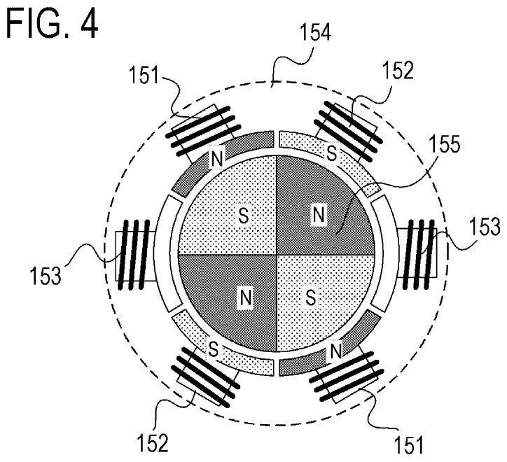

FIG. 4 is a configuration diagram of the motor 150. The motor 150 includes a 6-slot stator 154 and a 4-pole rotor 155. The stator 154 includes the coils 151 (U phase), 152 (V phase), and 153 (W phase) and each of the coils 151 to 153 is made conductive by star connection. Therefore, there are a total of six excitation phases: U-V, U-W, V-U, V-W, W-U, and W-V. For example, passing a current from the coil 151 (U phase) to the coil 152 (V phase) means performing excitation on the U-V phase in which the coil 151 (U phase) is excited to the N pole and the coil 152 (V phase) is excited to the S pole. The rotor 155 is constituted of permanent magnets and has two sets of S poles and N poles, and a rotational phase of the rotor 155 can be defined based on when the rotor 155 is at a predetermined position. For example, in the present embodiment, if the state shown in FIG. 4 is assumed to represent an electrical angle of 0, the electrical angle becomes 2π when the rotor rotates counterclockwise by a mechanical angle of π from the state shown in FIG. 4.

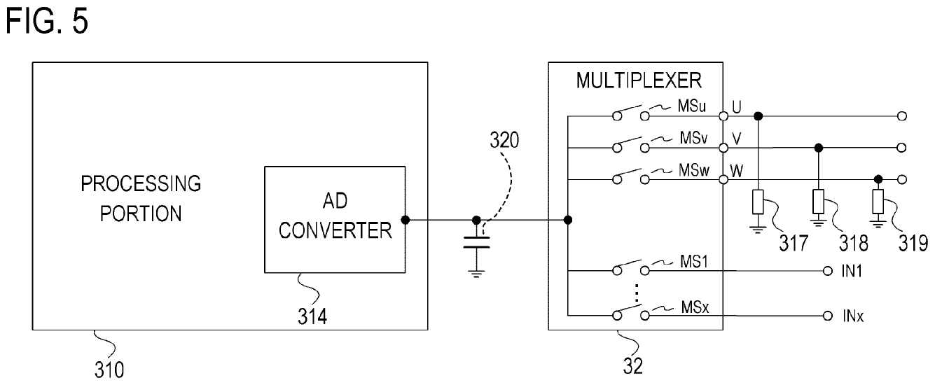

FIG. 5 shows a configuration of a current detecting portion. The AD converter 314 is connected to the shunt resistors 317, 318, and 319 of the respective phases via a multiplexer 32. The multiplexer 32 can be connected to each of the coils 151 (U phase), 152 (V phase), and 153 (W phase) of the motor 150 and a circuit having analog information other than the motor control portion 31 (not illustrated). The motor control portion 31 controls the inverter 316 based on a current measured by the computing portion 312 as a detection result of the current detecting portion.

Based on a command from the printer control portion 30, the multiplexer 32 controls on/off states of switching elements MS inside the multiplexer 32 so that a circuit with analog information to be read is connected to the AD converter 314. The switching element MS includes a switching element MSu, a switching element MSv, a switching element MSw, and switching elements MS1 to MSx in correspondence to the plurality of circuits to be selectively connected to the AD converter 314. After the voltage of the circuit for which the switching element MS inside the multiplexer 32 is turned on is charged to a sampling capacitor 320, the analog information of the circuit is read by the AD converter 314.

Here, switching noise occurs when switching on and off at the switching element MS inside the multiplexer 32. Therefore, when converting analog information into digital information at the AD converter 314, a read by the AD converter 314 is executed after providing a predetermined stand-by time (settling time) from the switching in the switching element MS inside the multiplexer 32. For example, when currents of the respective coils 151 (U phase), 152 (V phase), and 153 (W phase) are to be detected simultaneously, a current detection time of about 2 μs×3 phases=6 μs can be provided if the settling time is 2 μs per phase.

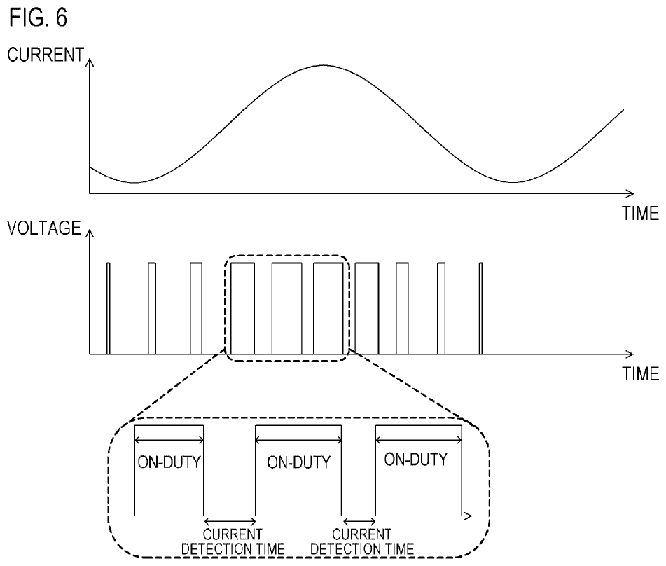

FIG. 6 shows an example of a PWM voltage waveform. When the gate driver 315 is controlled by the PWM port 311 and the switching elements IS1 to IS6 of the inverter 316 are turned on and off, PWM voltage as shown in FIG. 6 is input to each of the coils 151 to 153. As a result, a sinusoidal current flows as the current in each of the coils 151 to 153 as shown in FIG. 6. At this point, the PWM voltage is turned off for the current detection time including the settling time because, as described above, the high-side switching elements IS1, IS3, and IS5 must be turned off when currents are detected simultaneously. Therefore, the PWM voltage cannot be turned on for the current detection time during phases that require a high on-duty and a desired current cannot flow to the motor 150. For example, if a current detection time of 6 μs is to be provided with respect to a period of PWM voltage control of 50 μs, then the on-duty is to be limited to 88% at maximum.

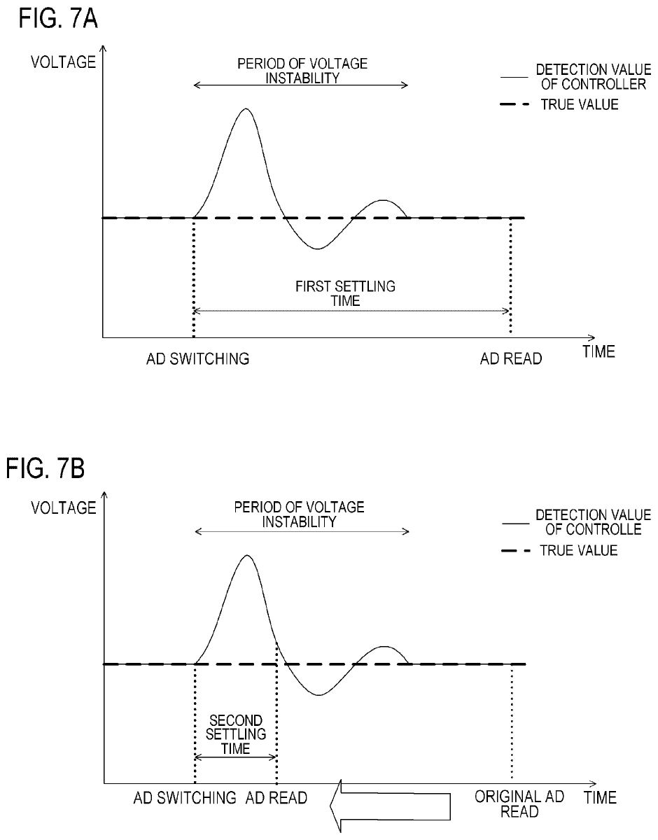

FIGS. 7A and 7B show examples of noise that can occur in the analog information read by the AD converter 314 during switching. In the multiplexer 32, at a timing when the switching element MS of the multiplexer 32 is switched to the circuit with analog information to be read by AD converter 314, noise occurs in the analog information and a period of voltage instability is created.

FIG. 7A shows an example of a case where a settling time being a general control is provided for a noise convergence period (first settling time). As shown in FIG. 7A, by performing an AD read at a timing where the state of voltage instability subsides and a detection value of the controller becomes equal to a true value, an error in current detection can be reduced and an unevenness of rotation of the motor 150 can be suppressed.

FIG. 7B shows an example of a case where the settling time is provided for a period of an AD read prior to noise convergence (second settling time). As shown in FIG. 7B, setting a shorter settling time as compared to the original AD read timing shown in FIG. 7A enables the current detection time to be reduced and on-duty of the PWM voltage to be raised.

Here, when performing an AD read prior to noise convergence as shown in FIG. 7B, since the error in the current detection value is large, unevenness of rotation of the motor 150 may increase. In this case, a state where the error in the current detection value is large can be described as, for example, a state where a current is detected that exceeds or falls below a predetermined range of currents that can be described as currents to be detected in a stable voltage state or, in other words, a state where the range of variation in a magnitude of the detected current is large. In addition, an unevenness of rotation of the motor 150 can be taken to mean periodic variations in the rotational speed of the motor 150. A state where the unevenness of rotation is large can be described as a state where an amount of periodic variations in the rotational speed of the motor 150 is large.

In the case of a motor used in an image forming apparatus such as the motor 150, an increase in unevenness of rotation during image formation may adversely affect the image to be transferred to the sheet 20. Therefore, a settling time is provided which allows a long enough wait for noise to converge after switching as shown in FIG. 7A or, in other words, long enough for variations in the voltage that the AD converter 314 reads from the shunt resistors 317 to 319 to converge within a predetermined range. For example, if the PWM cycle is 50 μs and the time required for a read by the AD converter is 2 μs, since 2 μs×3 phases=6 μs is required, a maximum duty value is 88%. On the other hand, at a timing where image formation is not performed, the adverse effect on the image forming apparatus is negligible even if the unevenness of rotation of the motor 150 increases. Therefore, at a timing where image formation is not performed such as during startup, a settling time for performing an AD read is provided which does not wait for noise convergence as shown in FIG. 7B or, in other words, at an early timing regardless of whether or not the variation in the voltage that the AD converter 314 reads from the shunt resistors 317 to 319 has converged within a predetermined range. Accordingly, the on-duty of PWM voltage control of the motor 150 can be raised to as high as nearly 100%, allowing smaller motors to be used. Specifically, if the time required for a read by the AD converter 314 is shortened from 2 μs to 0.5 μs in the case of a PWM period of 50 μs, the maximum duty value can be increased from 88% to 97%, which is close to 100%.

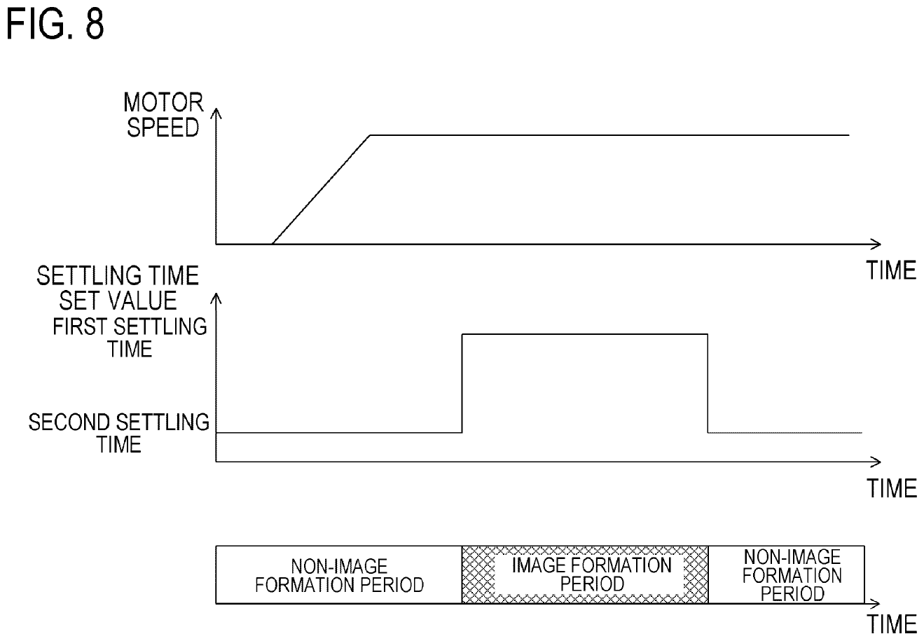

FIG. 8 shows a switching operation example of settling time. As described above, it can be said that using the first settling time during an image formation period and using the second settling time during a non-image formation period enables the advantages of each settling time to be enjoyed. Therefore, as shown in FIG. 8, during a period between the start of the motor and the start of image formation, an on-duty limit is set higher as the second settling time. On the other hand, the settling time is switched to the first settling time at a timing where image formation starts or after a predetermined time has elapsed after reaching a target speed.

In the current detection period during which the current detecting portion detects the current flowing in each of the coils 151 to 153, detection of the current is started after a predetermined settling time has elapsed after the application of voltage from the inverter 316 to each of the coils 151 to 153 of the motor 150 is stopped. For example, in a current detection operation during the image formation period (first current detection operation), the settling time is set so that current detection starts after the rotational speed of the motor 150 reaches a predetermined target speed and after a predetermined time has elapsed from the start of acceleration (first settling time). On the other hand, in a current detection operation during the non-image formation period (second current detection operation), the settling time is set so that current detection starts after the rotational speed of the motor 150 reaches a predetermined target speed and before the predetermined time elapses from the start of acceleration (second settling time). In other words, the second settling time is shorter than the first settling time, and the second current detection operation is a current detection operation in which current detection is started at an earlier timing than the lapse of the first settling time in the first current detection operation. Therefore, the current detection period when performing the second current detection operation is shorter than the current detection period when performing the first current detection operation, and the shorter period allows the inverter 316 more time to apply voltage to each of the coils 151 to 153 of the motor 150.

The first settling time may, for example, be set so that the first current detection operation can be executed after the variation in the rotational speed of the motor 150 relative to a predetermined target speed has converged within a predetermined range. In this case, the second settling time may be set so that the second current detection operation can be executed before the variation in the rotational speed of the motor 150 relative to the predetermined target speed converges within the predetermined range. Alternatively, the second current detection operation may be configured to be executed when, among operations of the image forming portion, an operation that places a greater load on the motor 150 than the operation that causes the first current detection operation to be executed is performed. For example, the switching of settling times may be an operation of switching to the first settling time after a predetermined time elapses from the motor speed reaching a target value and a state of light load being created under steady rotation. In other words, the first current detection operation may be executed during steady rotation of the motor 150 and the second current detection operation may be executed, for example, during startup or acceleration of the motor 150.

As described above, in the first current detection operation, the setting time is set to a duration that enables an amount of periodic variations in the rotational speed (unevenness of rotation) of the motor 150 to be kept at or below a predetermined magnitude. Accordingly, the unevenness of rotation of the motor 150 during image formation can be reduced. In addition, in the second current detection operation, the settling time is set to the shortest possible duration regardless of whether or not the unevenness of rotation occurs. This allows a shorter time to wait for the application of voltage to the motor 150 (allowing the application of voltage to the motor 150 to be executed at an earlier time) and a higher on-duty limit. Therefore, a motor drive voltage at a higher duty can be applied while stabilizing an image forming operation.

### Second Embodiment

In the first embodiment, a control example of a current detection time by switching between the first settling time and the second settling time at startup has been described. In the second embodiment, a control example of a current detection time by switching between the first settling time and the second settling time during load variations such as contact/separation will be described using FIGS. 1, 7A, 7B, and 9.

Hereinafter, descriptions of portions that are common to the first embodiment will not be repeated.

Generally, an image forming apparatus such as that shown in FIG. 1 has a mechanism to bring the photosensitive drum 11 and the developing roller 14 into contact with each other and to separate the photosensitive drum 11 and the developing roller 14 from each other from the perspective of the product life of the photosensitive drum 11. In other words, the photosensitive drum 11 and the developing roller 14 are configured to be capable of assuming a contact state of coming into contact with each other and a separation state (non-contact state) of separating from each other. Specifically, there are three states: a state where the photosensitive drums 11Y, 11M, 11C, and 11K and the developing rollers 14Y, 14M, 14C, and 14K are all in contact (full-color contact); a state where only the photosensitive drum K and the developing roller 14K are in contact (monochromatic contact); and a state where all of the photosensitive drums and developing rollers are separated (total separation). The switching of the contact/separation states is triggered by an actuator such as SL (not illustrated) and performed using power of the motor 150.

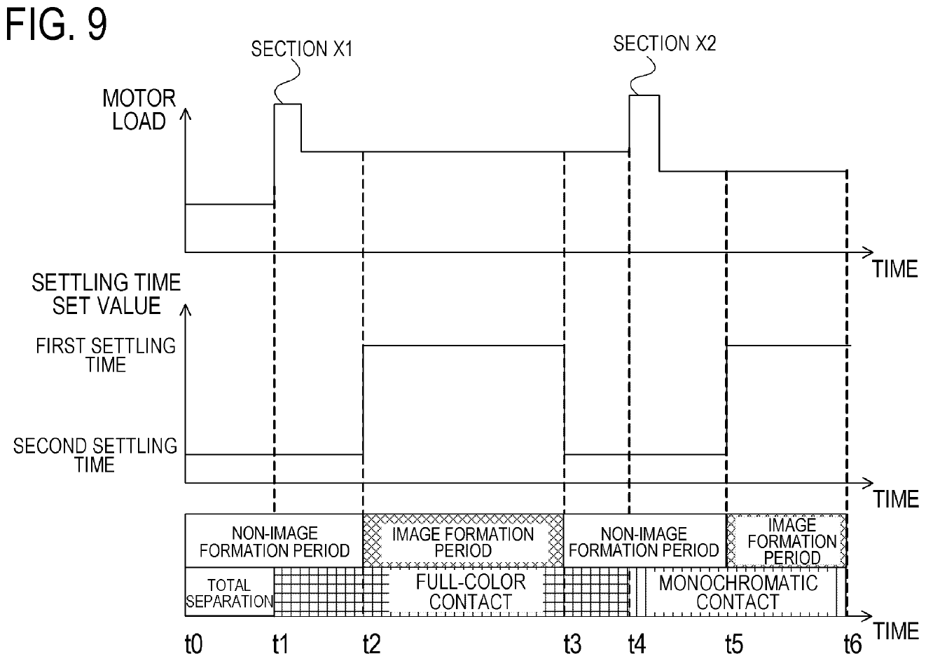

FIG. 9 shows a switching operation example of settling times during load variation according to the present embodiment. Here, a time point t1 is a timing at which the contact/separation state is switched from the total separation state to the full-color contact state. A time point t2 is a timing of transition from a non-image formation period to an image formation period. A time point t3 is a timing of transition from an image formation period to a non-image formation period. A time point t4 is a timing at which the contact/separation state is switched from the full-color contact state to the total separation state. A time point t5 is a timing of transition from a non-image formation period to an image formation period.

During a contacting/separating operation, since a mechanism for bringing the developing roller 14 into contact/separation has to be operated, the motor 150 that is a drive source is subjected to a load. For example, when switching of contact/separation states involving a transition from the total separation state to the full-color contact state is performed while the motor 150 is in steady rotation at the time point t1 in FIG. 9, a section X1 occurs in which a load variation in the image forming portion causes the motor load required for the motor 150 to be temporarily heavier. In a similar manner, a section X2 in which the motor load becomes temporarily heavier occurs when performing switching of contact/separation states at the time point t4.

As described in the first embodiment, since an AD read performed before noise convergence as shown in FIG. 7B may have an adverse effect on an image transferred onto the sheet 20, a settling time which allows a long enough wait for noise to converge as shown in FIG. 7A is provided in an image formation period. On the other hand, in a non-image formation period, since an adverse effect on the image forming apparatus is negligible even if the unevenness of rotation of the motor 150 increases, an AD read can be performed without having to wait for noise convergence as shown in FIG. 7B. Therefore, the second settling time can be set during non-image formation periods such as from time point t0 to time point t2 and from time point t3 to time point t5. As a result, with respect to sections in which motor load temporarily increases such as section X1 and section X2, the on-duty of PWM voltage control of the motor 150 can be raised to as high as nearly 100% and smaller motors can be used.

Configurations of the respective embodiments described above can be combined with each other.

According to the present disclosure, a motor drive voltage at a higher duty can be applied while stabilizing an image forming operation.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of Japanese Patent Application No. 2024-130098, filed on Aug. 6, 2024, which is hereby incorporated by reference herein in its entirety.

What is claimed is:

1. An image forming apparatus, comprising:
an image forming portion which forms an image onto a recording material;
a motor which generates a drive force for driving the image forming portion and which includes a plurality of coils;
an inverter which applies a voltage to the plurality of coils;
a current detecting portion which detects a current flowing in the plurality of coils; and
a control portion which controls the inverter, based on a detection result of the current detecting portion,
wherein the control portion controls the inverter so as to stop the application of the voltage during a current detection period for the current detecting portion to detect the current, and
wherein the current detecting portion is capable of executing, in the current detection period, a first current detection operation of starting detection of the current after a predetermined settling time elapses and a second current detection operation of starting the detection at an earlier timing than the lapse of the predetermined settling time.

2. The image forming apparatus according to claim 1,
wherein in a case where the settling time is a first settling time, the second current detection operation is a current detection operation that starts the detection after a lapse of a second settling time that is shorter than the first settling time.

3. The image forming apparatus according to claim 1,
wherein the current detection period in a case of performing the second current detection operation is shorter than the current detection period in a case of performing the first current detection operation.

4. The image forming apparatus according to claim 1,
wherein the first current detection operation is executed during an image formation period in which the image forming portion performs an image forming operation of forming an image onto a recording material, and
wherein the second current detection operation is executed during a non-image formation period in which the image forming portion does not perform the image forming operation.

5. The image forming apparatus according to claim 1,
wherein the second current detection operation is executed in a case where, among operations of the image forming portion, an operation is performed that places a greater load on the motor than the operation that causes the first current detection operation to be executed.

6. The image forming apparatus according to claim 1,
wherein the first current detection operation is executed during steady rotation of the motor, and
wherein the second current detection operation is executed during startup of the motor.

7. The image forming apparatus according to claim 1,
wherein the second current detection operation is executed during acceleration of the motor.

8. The image forming apparatus according to claim 1,
wherein the first current detection operation is executed after a rotational speed of the motor reaches a predetermined target speed and after a predetermined time has elapsed from the start of acceleration, and
wherein the second current detection operation is executed after the rotational speed of the motor reaches a predetermined target speed and before the predetermined time elapses from the start of acceleration.

9. The image forming apparatus according to claim 8,
wherein the first current detection operation is executed after a variation in the rotational speed of the motor relative to a predetermined target speed has converged within a predetermined range, and
wherein the second current detection operation is executed before the variation in the rotational speed of the motor relative to a predetermined target speed converges within the predetermined range.

10. The image forming apparatus according to claim 1,
wherein the control portion controls with a PWM signal a switching element of the inverter, and
wherein a voltage according to a duty of the PWM signal is applied to the plurality of coils.

11. The image forming apparatus according to claim 1,
wherein the current detecting portion detects the current using a plurality of shunt resistors connected in series to a ground terminal of the inverter so as to correspond to the plurality of coils.

12. The image forming apparatus according to claim 11,
wherein the current detecting portion includes an AD converter for converting a voltage corresponding to a current, which is acquired using the plurality of shunt resistors and which flows in the plurality of coils, into a digital value,
wherein the AD converter is connected to the plurality of shunt resistors via a multiplexer including a plurality of switching elements corresponding to the plurality of shunt resistors, and
wherein the settling time is a time after switching of the plurality of switching elements in the multiplexer until start of a read of the voltage from the shunt resistors by the AD converter.

13. The image forming apparatus according to claim 12,
wherein the first current detection operation is executed after a variation of the voltage to be read by the AD converter from the shunt resistors after the switching converges to a predetermined range, and
wherein the second current detection operation is executed before a variation of the voltage to be read by the AD converter from the shunt resistors after the switching converges to a predetermined range.

14. The image forming apparatus according to claim 1,
wherein the settling time is set to a duration that enables an amount of periodic variations in a rotational speed of the motor to be kept at not more than a predetermined magnitude.

15. The image forming apparatus according to claim 1,
wherein the image forming portion includes an image bearing member and a developer bearing member,
wherein the image bearing member and the developer bearing member are configured to be capable of assuming a contact state of coming into contact with each other and a separation state of separating from each other, and
wherein the second current detection operation is executed in a case where an operation of contact/separation of the image bearing member and the developer bearing member is performed.
